(19) United States
(12) Patent Application Publication
(10) Pub. No.: US 2024/0298551 A1
(43) Pub. Date: Sep. 5, 2024

(54) QUANTUM DOT STRUCTURES COMPRISING AN INTEGRATED SINGLE ELECTRON TUNNELING READOUT AND SINGLE ELECTRON TUNNELING QUANTUM DOT READOUT STRUCTURES

(71) Applicant: Technische Universiteit Delft, Delft (NL)

(72) Inventors: Menno Veldhorst, Delft (NL); Nico Willem Hendrickx, Delft (NL)

(21) Appl. No.: 18/574,531

(22) PCT Filed: Jun. 29, 2022
(86) PCT No.: PCT/NL2022/050373

§ 371 Date: Dec. 27, 2023

(30) Foreign Application Priority Data
Jun. 29, 2021 (NL) 2028580

(51) Int. Cl. H10N 60/10; G06N 10/40

(52) U.S. Cl. CPC H10N 60/11; G06N 10/40; H10N 60/128

(57) ABSTRACT

An integrated quantum dot structure comprises: one or more semiconductor layers arranged on a substrate; a single electron tunneling (SET) transistor formed in or over the one or more semiconductor layers, the SET transistor comprising a source and a drain connected by tunneling junctions to a conductive island; a plurality of quantum dot regions, preferably an array, arranged around the SET transistor, the plurality of quantum dot regions being formed in the one or more semiconductor layers and the SET transistor being configured to readout change states of the plurality of quantum dot regions; one or more insulating layers provided over the SET transistor and the quantum dot regions; a source electrode and a drain electrode arranged over the one or more insulating layers; and, first and second nano-scale metallic vias connecting the source and drain of the SET transistor to the source and drain electrodes respectively.

### CROSS-REFERENCE TO RELATED APPLICATION(S)

This Application is a Section 371 National Stage Application of International Application No. PCT/NL2022/050373, filed Jun. 29, 2022 and published as WO 2023/277687 A1 on Jan. 5, 2023, in English, and further claims priority to Netherlands application Ser. No. 2028580, filed Jun. 29, 2021, the contents of which are hereby incorporated by reference in their entirety.

### TECHNICAL FIELD

The invention relates to single electron tunneling (SET) transistor and single hole tunneling (SHT) based quantum dot readout structures, and, in particular, though not exclusively, to quantum dot arrays comprising one or more integrated SET or SHT transistor readout structures.

### BACKGROUND

Increasing the number of qubits of a qubit processer will present technological challenges including interconnects, imperfect device yield, qubit calibration and qubit readout. A common method for a qubit readout of a spin state of a quantum dot qubit relies on spin-to-charge conversion which can be measured with a sensitive charge sensor such as a single-electron tunnelling (SET) or single hole tunnelling (SHT) transistor. Typically, in such readout scheme the charge sensor is positioned on the edges of a simple quantum dot structure, e.g. a double dot system or a linear array, as they require ohmic channels to allow for a transport measurement. Examples of SET transistor-based readouts structures for few qubit structures and one-dimensional (1D) qubit arrays are known. For example, US2019/0198618 describes sets of 1D arrays of quantum dots, wherein each 1D array is associated with a SET transistor for readout. Similarly, C. Jones et al., Logical Qubit in a Linear Array of Semiconductor Quantum Dots Phys. Rev. X 8, 021058—1 Jun. 2018, describe an example of a linear array of quantum dots implemented as a logical qubit coupled to a SET readout.

In the prior art, it is generally acknowledged that SET transistor-based qubit readout schemes are not or at least less suitable for reading qubits located within in a two-dimensional qubit structure, because the architecture is not scalable. Numerous articles, for example, A. West et al. Gate-based single-shot readout of spins in silicon, nature nanotechnology 14, pp. 437-441, G. Zheng et al. Rapid high-fidelity gate-based spin read-out in silicon, nature nanotechnology 14, pp. 742-746, and S. Schaal et al. Fast gate-based readout of silicon quantum dots using Josephson parametric amplification Phys. Rev. Lett. 124, 2020 refer to this problem and propose various alternative readout schemes, typically resonant type readout schemes. These schemes significantly increase the complexity of the fabrication. In addition, high-quality resonators have large footprints of typically 100×100 μm, significantly increase the device size, compared to typical quantum dot sizes of 50×50 nm. Scaling such resonators to large numbers and implementing such scheme into a scalable readout scheme for 2D qubit arrays of extended size are still open questions.

Various architectures for large area 2D qubit arrays have been proposed. For example, US, 10,692,924 and the article Silicon CMOS architecture for a spin-based quantum computer, Nature Communications, 8: 1766, by Veldhorst et al described operation of a 2D array of quantum dot qubits operated by a CMOS circuit layer that is provided over the 2D qubit array. These designs are based on local transistor-controlled charge detection but require extensive downscaling and new design of the CMOS circuitry. A further scheme is based on shared control, wherein plunger and/or barrier gates are controlled via a single shared line. For example, Li et al, propose in their article a crossbar network for silicon quantum dot qubits, Sci. Adv. 2018, a large scale 2D qubit array based on a crossbar design for controlling a large number of qubits. This scheme relies on dispersive readout structures for readout of rows of qubits. The design, which includes gate lines that are shared by multiple qubits, provides a relatively simple and scalable wiring structure for a qubit processor. However uniform fabrication parameters to ensure variability in threshold voltage, charging energy and tunnelling coupling between different sites is needed. To date, accurate control of the variability between qubits still poses significant challenges. Such shared line does not provide local control in the two-dimensional array of quantum dot and therefore can only work if the system is sufficiently uniform. The requirements on the uniformity are well beyond any practical demonstration in the literature, thus questioning its feasibility.

Hence, from the above it follows that there is a need in the art for quantum dot arrays comprising integrated SET readout structures. In particular, there is a need for a SET readout structure that can be used as readout structures for large-area quantum dot arrays that are operated as qubits.

### SUMMARY

It is an objective of the embodiments to reduce or eliminate at least one of the drawbacks known in the prior art.

In a first aspect, the embodiments relate to an integrated quantum dot structure which may comprise: one or more semiconductor layers arranged on a substrate; a single electron tunneling (SET) transistor formed in or over the one or more semiconductor layers, the SET transistor comprising a source and a drain connected by tunneling junctions to a conductive island; a plurality of quantum dot regions, preferably an array of quantum dot regions, arranged around the SET transistor, the plurality of quantum dot regions being formed in the one or more semiconductor layers and the SET transistor being configured to readout change states of the plurality of quantum dot regions; one or more insulating layers provided over the SET transistor and the quantum dot regions; a source electrode and a drain electrode arranged over the one or more insulating layers; and, first and second nano-scale metallic vias connecting the source and drain of the SET transistor to the source and drain electrodes respectively. In an embodiment, the SET transistor may be capacitively coupled to the plurality of quantum dot regions.

The embodiments further relate to an integrated quantum dot structure comprising: one or more semiconductor layers arranged on a substrate; a plurality of single electron tunneling (SET) transistors formed in or over the one or more semiconductor layers, each of the plurality of SET transistors comprising a source and a drain connected by tunneling junctions to a conductive island; a plurality of quantum dot regions, preferably an array of quantum dot regions, arranged around each of the plurality of SET transistors, the plurality of quantum dot regions being formed in the one or more semiconductor layers and each of the plurality of SET transistors being configured to readout change states of the plurality of quantum dot regions; one or more insulating layers provided over the plurality of SET transistors and the quantum dot regions; a source electrode and a drain electrode arranged over the one or more insulating layers; and, first and second nano-scale metallic vias connecting the source and drain of at least part of the plurality of SET transistors to the source and drain electrodes respectively.

In an embodiment, the integrated quantum dot structure may further comprise: a third nano-scale metallic via connecting a plunger electrode that is capacitively connected to the conductive island to a gate electrode arranged over the one or more insulating layers.

Thus, in contrast to prior art quantum dot readout structures, one or multiple SET transistors may be formed in or over an array of quantum dots, wherein the source, drain and gate electrodes of a SET transistor are formed in a different layer than the source and drain regions and the gate of the SET transistor. This way, a SET transistor readout structure can be realized wherein the quantum dot regions are formed around a SET transistor so that a large number of quantum dot regions can be read out. Nano-scale metallic vias may galvanically connect the source and drain of the SET transistor with the source and drain electrodes. The SET readout structure is easily scalable by integrating a plurality of such SET readout structures regularly distributed over a large area quantum dot structure.

It is well known that single charge carrier devices such as a SET transistor can implemented based materials that have mobile electrons or mobile holes. Hence, in this application the term SET transistor should be construed as encompassing both single-electron tunnelling (SET) transistors and single hole tunnelling (SHT) transistors.

In an embodiment, the SET transistor may be formed in the one or more semiconductor layers.

In an embodiment, the conductive island may be a quantum dot region formed in the one or more semiconductor layers and wherein the source and drain region regions of the SET may be formed in the one or more semiconductor layers.

In an embodiment, one end of the first metallic via and one end of the second metallic via may form Ohmic contacts, preferably nano-scale Ohmic contacts, with the one or more semiconductor layers.

In an embodiment, the SET transistor may be formed in a metallic or doped layer formed over the more semiconductor layers.

In an embodiment, the cross-sectional dimensions of the nano-scale metallic vias may be selected between 500 and 20 nm, preferably between 300 and 20 nm, more preferably between 200 and 20 nm.

In an embodiment, a first metallic via may connect the source electrode with the source of the SET transistor and a second metallic via may connect the drain electrode with the drain of the SET transistor.

In an embodiment, the quantum dot regions in the array of quantum dot regions may be separated by barrier regions.

In an embodiment, integrated quantum dot structure may further comprise: a barrier electrode structure comprising a barrier electrode arranged in one direction over the quantum dot structure; a second barrier electrode arranged in a second direction over the quantum dot structure, wherein the first barrier electrode and second barrier electrode cross each other at a first barrier region of the barrier regions. The first and second barrier electrode may form a multi barrier electrode structure for electrostatically controlling the coupling between a first quantum dot and a second quantum dot separated by the first barrier region. Thus, barriers regions between the quantum dot regions may be locally controlled using barrier electrodes. Quantum dots may be configured as qubits and by locally controlling a barrier region between two qubits, the coupling between the qubits can be controlled. The state of the quantum dots before and after interaction can be measured using the SET transistor as a highly sensitive charge sensor which may be capacitively coupled to the quantum dots.

In an embodiment, the dimensions of the quantum dot regions may be selected between 200 and 20 nm, preferably 100 and 40 nm.

In an embodiment, at least part of the barrier electrodes, the gate electrodes and/or the metallic vias may be made of metal that becomes superconductive below a critical temperatures. In an embodiment, metals for the metal vias include Al, Nb, NbN, TiN, NbTiN. These metals will become superconducting below a certain critical temperature. Thus providing very low loss electrodes. In a further embodiment, platinum may be used as a metal for the vertical vias thereby forming Pt—SiGe or Pt—Ge contacts. An annealing step may be used to form an alloy at the interface of this contacts in to form a platinum silicide compound such as platinum silicide PtSi or platinum germanosilicide PtSiGe or a platinum germanide compound such as platinum germanide PtGe; These platinum silicide and germanide alloys will become superconducting below a critical temperature thus providing very low loss superconducting ohmic contacts with the quantum well.

In an embodiment, the one or more semiconductor layers may include a semiconductor heterostructure, a MOS structure, a semiconductor-on-insulator structure such as silicon-on insulator SOI, or geometries such as finfet, nanowires, hut wire and self-assembled structures.

Particular suitable silicon based semiconductor quantum dot platforms include silicon-compatible quantum dot structures including silicon-germanium heterostructures and 20 silicon metal-oxide-semiconductor (SiMOS) structures. Examples of such structures are describe in the article by Lawrie et al, Quantum Dot Arrays in Silicon and Germanium, Appl. Phys. Lett. 116, 080501 (2020), which is hereby incorporated by reference into this application. For example, in an embodiment, the semiconductor layer stack may include a Silicon substrate, an intrinsic Silicon layer, an isotopically purified Silicon (²⁸Si) epitaxial layer and a SiO2 layer. In another embodiment, the semiconductor layer stack may include a Si/SiGe heterostructure formed on a Silicon substrate, wherein the Si/SiGe heterostructure may include a graded Si1 xGex layer and an isotopically purified Silicon (28Si) epitaxial layer between two SiGe layers. In another embodiment, the semiconductor layer stack may include a Ge/SiGe heterostructure formed on a Silicon substrate, wherein the Ge/SiGe heterostructure includes a Germanium layer formed on the Silicon substrate followed by a reversed graded Si₁₋ₓGeₓ and a Ge epitaxial layer between two SiGe layers.

In an embodiment, the plurality of quantum dot regions may form a 2D array of quantum dot regions or a 3D array of quantum dot regions. In an embodiment, pitch between neighboring quantum dots (the inter-dot pitch) in the array may be selected between 200 and 50 nm.

In a further aspect, the embodiments may relate to a quantum processor comprising an integrated quantum dot structure according to any of the embodiments described in this application.

In yet a further aspect, the embodiments may relate to a single electron tunneling (SET) quantum dot readout structure comprising: one or more semiconductor layers arranged on a substrate; a quantum dot connected by tunnel junctions to a source area and a drain area, the quantum dot, the tunnel junctions and the source and drain area forming a SET transistor being formed in or over the one or more semiconductor layers; the SET transistor being configured to read out a plurality of quantum dot structures arranged around the SET transistor and formed in the one or more semiconductor layers; one or more insulating layers provided over the SET transistor; a source electrode and a drain electrode arranged over the one or more insulating layers; and, first and second nano-scaled metallic vias connecting the source and drain of the SET transistor to the source and drain lines respectively.

In an embodiment, the readout structure may further comprise: a third nano-scale metallic via connecting a plunger electrode that is capacitively connected to the conductive island to a gate electrode arranged over the one or more insulating layers.

In an embodiment, the SET transistor may be formed in the one or more semiconductor layers or the SET transistor may be formed in a metallic or doped layer formed over the more semiconductor layers.

The embodiments will be further illustrated with reference to the attached drawings, which schematically will show embodiments according to the invention. It will be understood that the invention is not in any way restricted to these specific embodiments.

### BRIEF DESCRIPTION OF THE DRAWINGS

FIG. 1A and 1B depict a schematic of a quantum dot array comprising an integrated SET readout structure according to an embodiment of the invention;

FIG. 2A and 2B depict schematics of a barrier electrode structure for a quantum dot array according to an embodiment of the invention;

FIG. 3A and 3B depict barrier electrode structures for a quantum dot array according to various embodiments of the invention;

FIG. 4A-4C depict a top view and two cross sections of a semiconductor structure according to an embodiment of the invention comprising a first barrier electrode structure.

FIG. 5A-5C depict a top view and two cross sections of the semiconductor structure according to an embodiment of the invention comprising a double barrier electrode structure;

FIG. 6A-6C depict a top view and two cross sections of the semiconductor structure according to an embodiment of the invention .

FIG. 7 depicts a schematic of a semiconductor structure according an embodiment of the invention;

FIG. 8A-8C depict a top view and two cross sections of the semiconductor structure according to an embodiment of the invention ;

FIG. 9A-9C depict a top view and two cross sections of the semiconductor structure according to an embodiment of the invention ;

FIG. 10 depicts an ohmic connection to an integrated SET transistor readout structure according to an embodiment of the invention;

FIG. 11A-11C depict an integrated SET-based readout structure for quantum dot arrays according to another embodiment of the invention;

FIG. 12A and 12B depicts pictures of 2D quantum dot arrays according to various embodiments of the invention.

### DESCRIPTION OF THE EMBODIMENTS

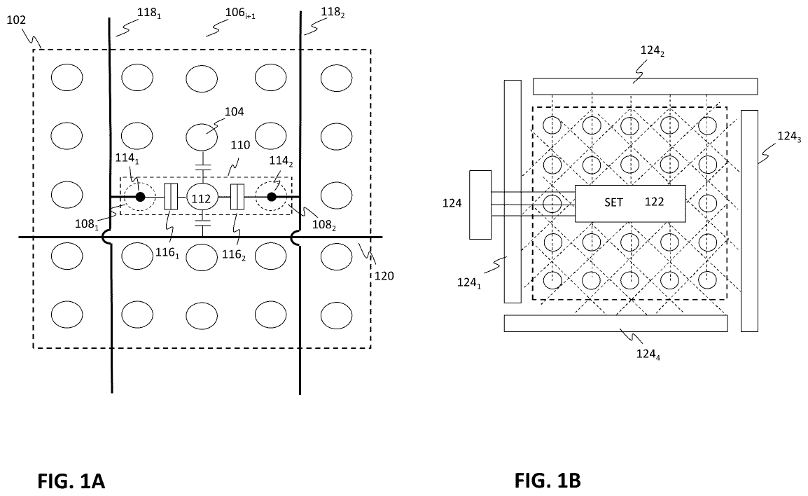

The embodiments in this disclosure describe readout structure for large area quantum dot arrays. In particular, the embodiments in this disclosure aim to provide SET readout structures that can be integrated in a quantum array structure. The SET read structures are integrated within central parts of the quantum dot array. FIG. 1A and 1B depicts a schematic of a quantum dot array comprising an integrated SET readout structure according to an embodiment of the invention. In particular, FIG. 1A represents a schematic top view of part of semiconductor substrate 102 comprising regions 104 in which a quantum dot may be formed. The quantum states of a quantum dot, e.g. the spin state of a single charge carrier, e.g an electron or hole, in the quantum dot, may be operated as a qubit.

Different types of quantum dots may be used, e.g. quantum dots formed in a stack of semiconductor layers in which a two-dimensional electron gas (2DEG) or a two-dimensional hole gas (2DHG) is formed. Such stack may be referred to as a quantum well stack, which are well known in the field. Quantum well stacks may be based on group IV type, group III-V and group II-VI type thin-film semiconductors layers. Other types of quantum dots which may be used with the embodiments in this disclosure include nano-wire type quantum dots, MOS-type quantum dots or self-assembled quantum dots.

Gate electrodes may be arranged over the substrate wherein each electrode may be connected to a plurality of plunger gates. Further, one or more dielectric layers may be used to separate the gate electrodes from the semiconductor layers in which the quantum dots are formed. A gate electrode may be used to control the potential of a row of quantum dots. In particular, such gate electrode may be used to control the number of charge carriers in the quantum dot. Examples of electrode structures for controlling the quantum dot and the SET transistor will be described hereunder in more detail.

A readout area 110 located inside (i.e. within) the quantum dot array may comprise a readout structure for quantum dots arranges around the readout structure. Thus, the SET transistor is located in the central part of the quantum dot array, away from the quantum dots that form the peripheral part of the quantum dot array. Quantum dot array 102 depicted in the figure may be part of an extended, densely packet quantum dot array of hundreds or even thousands quantum dot regions. For example, the quantum dot array including the SET readout structure may form a unit cell of a large area quantum dot array with a plurality of SET readout structures arranged within the quantum dot area.

In some of the embodiments, the readout area may include space for forming a single electron tunneling (SET) transistor within quantum dot array. The readout areas may include source and drain regions 108_{1,2} and a small conductive island 112 formed between the source and drain regions. The source and drain regions may be connected to source and drain electrode that are provided over the 2D quantum dot array. One or more dielectric layers may be used to separate the source and drain electrode from the gate electrode.

Metallic nano-scale vias 1141,2 in the dielectric layer may be used to electrically connect the source and drain regions of the SET in the semiconductor layer with the source and drain electrodes. The SET island may be connected to the source and drain regions via tunnel barriers 116_{1,2}. Further, a SET transistor gate line 120 may be connected to a plunger gate that is capacitively coupled to the island of the SET transistor. The SET gate electrode may be used to tune the SET transistor so that it can be used as a highly sensitive charge sensor for sensing charge transitions in quantum dots, e.g. quantum dot 104, that is capacitively coupled to the metallic island of the SET transistor.

In some embodiments, the barriers regions between the quantum dots in FIG. 1A may be locally controlled using barrier electrodes. Quantum dots may be configured as qubits and by locally controlling a barrier region between two qubits, the coupling between the qubits can be controlled. The state of the quantum dots before and after interaction can be measured using the SET transistor as a highly sensitive charge sensor which is capacitively coupled to the quantum dots.

FIG. 1B schematically depicts a quantum dot processor comprising an array of quantum dots including an electrode structure arranged over the quantum dot array for controlling the quantum dots (e.g. gate electrodes) and the coupling between quantum dots (e.g. barrier electrodes). These electrodes may be connected to control electronics 124₁₋₄ arranged along the sides of the quantum dot array. The SET transistor 122 is arranged within the quantum dot array (away from the edges) so that quantum dots may be readout by the SET transistor, which is connected via electrodes to a SET controller 124. The different electrodes provided over the quantum dot array may be separated by insulating layers and nano-scale metallic vias through the insulating layers may be used to make contact between conductive structures, including the semiconductor layers in which the quantum dots are formed.

Thus, in contrast to prior art quantum dot readout structures, a SET transistor may be formed in a readout area within the array of quantum dots, wherein the source and drain electrodes of the SET transistor are formed in a different layer than the source and drain regions of the SET transistor and nanoscale metallic vias may galvanically connect the source and drain of the SET transistor with the source and drain electrodes. The SET readout structure is easily scalable by integrating a plurality of such SET readout structures regularly distributed over a large area quantum dot structure.

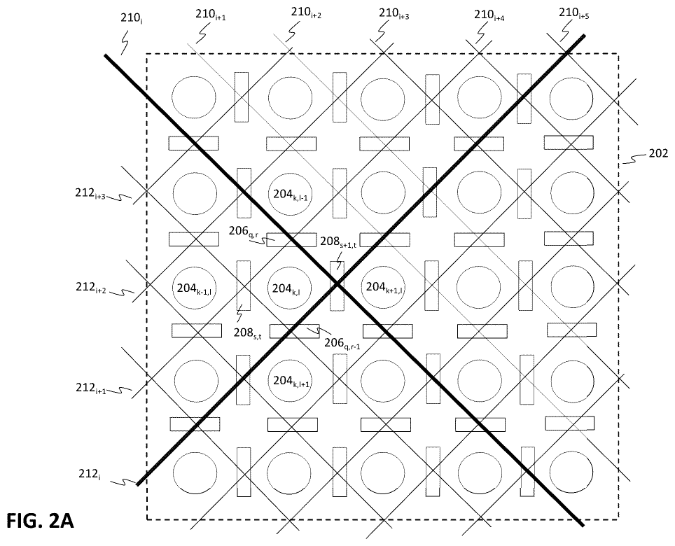

FIG. 2A and 2B depict schematics of a quantum dot array comprising a scalable quantum dot coupling structure according to an embodiment of the invention. FIG. 2A represents a schematic top view of part of semiconductor substrate 202 comprising regions 204_{k,l}, in which a quantum dot may be formed. The quantum states of a quantum dot, e.g. the spin state of a single charge carrier e.g an electron or hole in the quantum dot, may be used to configure and operate a quantum dot as a qubit. Different types of quantum dots may be envisaged, e.g. quantum dots formed in a stack of semiconductor layers in which a two-dimensional electron gas (2DEG) or a two-dimensional hole gas (2DHG) is formed. The quantum dot regions may be arranged in an array of k rows and I columns.

The quantum dot regions may be separated by barrier regions, in particular first barrier regions located between neighboring quantum dots in a row. These first barrier regions may be referred to as row barriers. Further, second barrier regions may be located between neighboring quantum dots in a column. These second barrier regions may be referred to as column barriers. This way, a quantum dot 204_{k,l} within the 2D array may have a plurality of neighboring quantum dots 204_{k-1,l}, 204_{k+1,l}, 204_{k,l-1}, 204_{k,l+1}, in this example four quantum dots, separated by first (column) barrier regions 206_{q,r}, 206_{q,r-1} and second (row) barrier regions 208_{s,t}, 208_{s+1,t}. These barrier regions may be controlled based on barrier electrodes that are arranged over the substrate as shown in the figure.

A set of first barrier electrodes may be arranged in a first direction, in this example a first diagonal direction, over the substrate such that each first barrier electrode may be arranged over a first plurality of column and/or row barriers regions so that each first barrier electrode electrostatically couples to the first plurality of column and/or row barriers regions. . . . For example, in the embodiment depicted in FIG. 2A, the first barrier electrodes may be alternately arranged over column and row barriers in a first direction. Similarly, a set of second barrier electrodes may be arranged in a second direction, in this example a second diagonal direction, over the substrate such that second barrier electrode may be arranged over a second plurality of column and/or barrier regions so that each second barrier electrode electrostatically couples to the second plurality of column and/or row barriers regions. For example, the second barrier electrodes may be alternately arranged over column and row barriers in a second direction. The electrodes may be arranged such that at each barrier region, at least two barrier electrodes, a first barrier electrode in a first direction, and a second barrier electrode, meet or cross each other, so each barrier region is coupled, preferably electrostatically, to two (or more) barrier electrodes and so that each barrier region can be effectively controlled by the two barrier electrodes. Although FIG. 2A depicts a diagonal arrangement of barrier electrodes, other angular arrangements e.g. horizontal and vertical, are also possible.

As shown in FIG. 2B, by controlling barrier electrodes 210ₗ and 212ₗ, barrier region 208_{s+1,t} between neighboring quantum dots 204_{k,l}, 204_{k+1,l} may be controlled. For example, a voltage for barrier electrodes 210ₗ and 212ₗ, may be selected such that if a voltage is applied to both electrodes, coupling between quantum dots 204_{k,l}, 204_{k+1,l} may be achieved. This way, local control of the coupling between quantum dots in the 2D array can be achieved. For example, as shown in FIG. 2B, the potential on two barrier gate electrodes 210ₗ, 212ₗ that control barrier region 208_{s+1,t} may be changed so that the states of the two quantum dots may become entangled. Local barrier control may also be used when integrating a single electron tunneling (SET) transistor within the 2D quantum dot array. Examples of such applications will be described hereunder in more detail with reference to the figures.

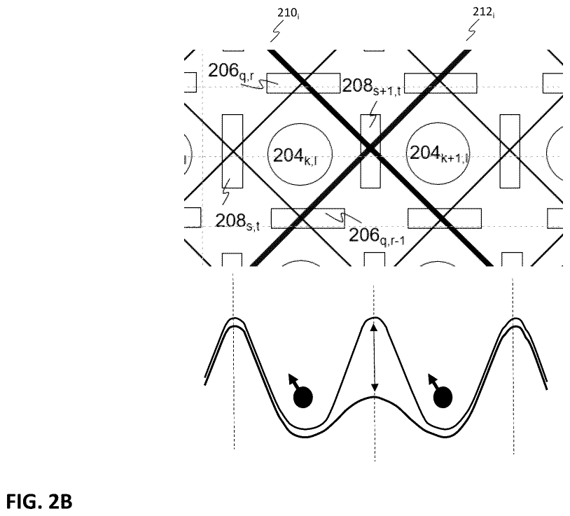

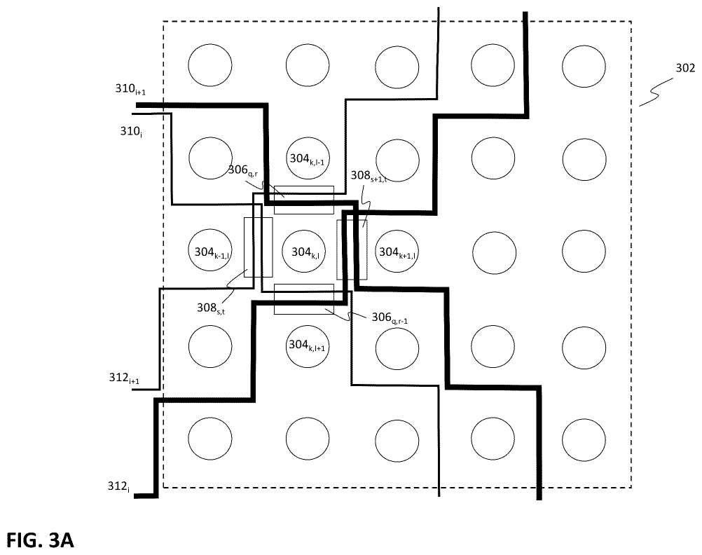

FIG. 3A depicts a quantum dot array comprising a scalable quantum dot coupling structure according to an embodiment of the invention. In particular, the figure illustrates an implementation of the barrier electrodes for providing local coupling of quantum dots in the 2D array of quantum dots. In this particular embodiment, a set of staircase-shaped first barrier electrodes 310ₗ, 310ᵢ₊₁ may be arranged in a first diagonal direction over a substrate 302 and a set of staircase-shaped second barrier electrodes 312ₗ, 312ₗ₊₁ may be arranged in a second diagonal direction over the substrate (for clarity reasons only a few (in this example four) barrier electrodes are visible in the figure).

The first and second set of staircase-shaped barrier electrodes may be arranged in the peripheral part of the areas that form the quantum dots. This way, further plunger gate electrodes can be arranged in the central part of the quantum dot area. Such plunger gates may be needed to create a quantum dot in the semiconductor layers. Each staircase barrier electrode includes vertical parts and horizontal parts. In order to electrically isolate the two sets of barrier electrodes, the electrodes may be formed in different layers on the substrate including at least one dielectric layer for electrically separating both barrier electrodes.

As shown in the figure, the barrier electrodes are arranged to define quantum dots 304_{k-1,l}, 304_{k+1,l}, 304_{k,l}, 304_{k,1-l}, 304_{k,l+1} separated by first (column) barrier regions 306_{q,r}, 306_{q,r-1} and second (row) barrier regions 308_{s,t}, 308_{s+1,t}. A barrier region may be controlled by a first barrier electrode in the first diagonal direction and a second barrier electrode in the second diagonal direction. For example, vertical barrier region 308_{s+1,t} may be controlled by a vertical part of first barrier electrode 310ᵢ₊₁ and a vertical part of the second barrier electrode 312ₗ. Similarly, horizontal barrier region 306_{q,r-1} may be controlled by a horizontal part of first barrier electrode 310ₗ and a horizontal part of the second barrier electrode 312ₗ. For clarity reasons, only a few barrier electrodes 310ₗ, 310ₗ₊₁, 312ₗ, 312ₗ₊₁ are illustrated. Further barrier electrodes may be arranged over the substrate so that all barrier regions between the quantum dots can be locally controlled.

In operation, a voltage may be applied to a pair of barrier electrodes that cross each other above a barrier area between two quantum dots (similar to the situation depicted in FIG. 1). The voltages may be selected such that a voltage applied to only one of the electrodes in the barrier areas still provides a sufficient potential barrier for decoupling the quantum dots. In contrast, applying a voltage to both electrodes that control vertical barrier region 308_{s+1,t} may lower the coupling barrier and allow coupling between the two quantum dots that are separated by this vertical barrier region.

FIG. 3B depicts a quantum dot array comprising a scalable quantum dot coupling structure according to another embodiment of the invention. Also this embodiment, includes barrier electrodes for providing local coupling of quantum dots in the 2D array of quantum dots. However, in contrast to the staircase type electrodes depicted in FIG. 3, in this particular embodiment, pairs of metal strips are arranged over the vertical and horizontal barrier regions between the quantum dot regions. The metal strip pairs are arranged in a layer and electrically isolated from each other.

Thus, metal strip pairs may be arranged horizontally and vertically to define quantum dots regions 304_{k-1,l}, 304_{k,l}, 304_{k+l,1}, 304_{k,1-1}, 304_{k,1+1} separated by first (column) barrier regions 306q,r, 306q,r-1 and second (row) barrier regions 308s,t, 308s+1,t. Then, a first insulating layer may be formed over the quantum dot regions and openings may be formed in the first insulating layer at positions of the metal strip pairs to expose one of the underlying metal strips. The openings may be arranged in a first direction over the quantum dot array. Metal vias 310ₗ may be formed in the openings to form first vertical metallic vias in the first insulating layer. A first barrier electrode 322ₗ may be formed over the first metallic vias. This way, a first barrier electrode may be formed connecting horizontal and vertical metal strips in the peripheral part of (the vertical and horizontal) barrier regions between the quantum dots.

A further second insulating layer may be formed over the structure to insulate the first barrier electrode from a further second barrier electrode 320ₗ, which may be formed over the quantum dot array in a second direction. The second barrier electrode may be formed in a similar was the first barrier electrode, i.e. formation of openings arranged in a second direction over the quantum dot array in the first and second insulating layers to expose one of the underlying metal strips, formation of metallic vias in the openings and a second barrier electrode formed over the metallic vias to form the second barrier electrode.

As shown in the figure, the first and second barrier electrodes 320ₗ, 322ₗ control the voltage over the two metal strip pairs arranged over barrier region 308_{s+1,t} between quantum dots 304_{k,l}, 304_{k+1,l}. For clarity reasons, only two barrier electrodes 3101, 322ₗ are illustrated. Further barrier electrodes may be arranged over the substrate so that all barrier regions between the quantum dots can be locally controlled.

Thus, the examples in these figures illustrate the use of barrier electrodes that allow local control of a barrier region between two quantum dots in a large quantum dot array. It is submitted that the electrode structures depicted in FIG. 3A and 3B are non-limiting examples and many different variations exist without departing the essence of the invention.

For example, barrier electrodes of FIG. 3A may be combined with barrier electrodes of FIG. 3B. Further, instead of two barrier electrodes to control a barrier region, three or more barrier electrodes may be used.

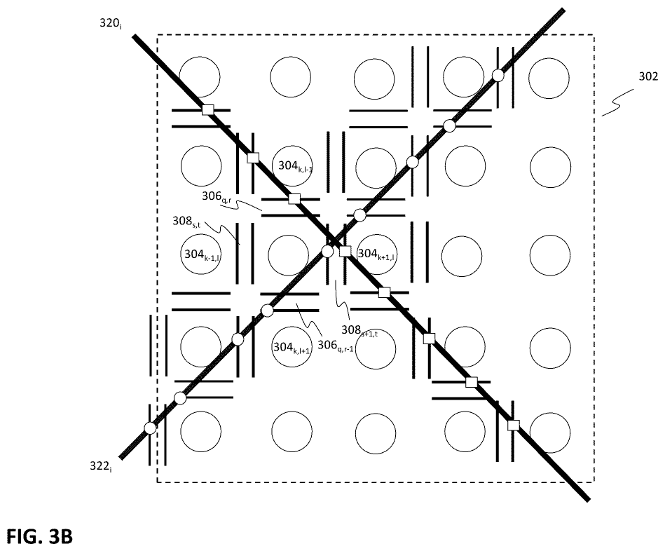

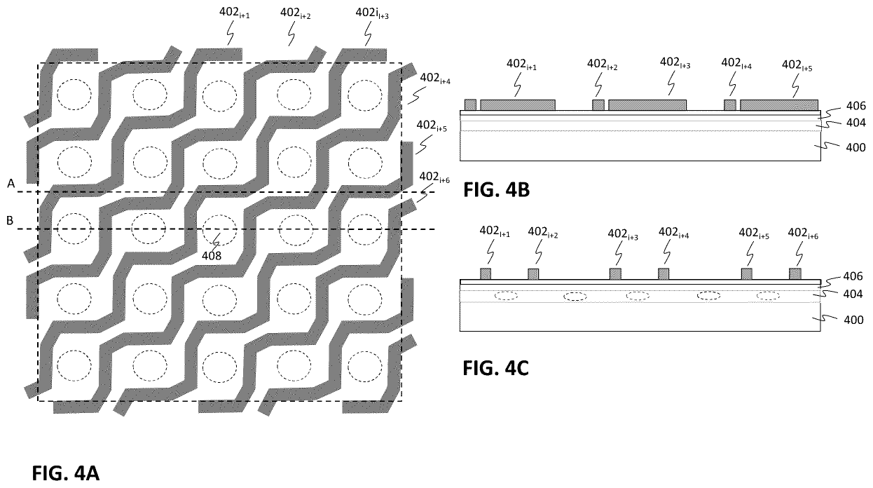

FIG. 4-9 illustrate a method for forming a quantum dot structure including an integrated SET structure according to an embodiment of the invention. These integrated structures may be realized based on fabrication techniques that are known in the field of semiconductor technology, including thin-film deposition techniques such as chemical vapor deposition CVD or atomic layer deposition ALD, and lithography techniques and dry and/or wet (selective) etching techniques based on patterned masks. In particular, FIG. 4A-4C depict a top view and two cross sections of a semiconductor structure after first fabrication steps in which a first barrier electrode structure is formed on a semiconductor structure. As shown in FIG. 4B and 4C, the semiconductor structure includes a substrate 400 comprising one or more semiconductor layers 404 in which quantum wells may be formed. For example, a quantum well may be formed in the semiconductor layers by applying a voltage to a plunger gate that is realized over the quantum dot region 408 as defined by the electrode structure. Examples of such plunger gate structures are described hereunder in more detail.

A first insulating layer 406 may be formed over the semiconductor layers. As shown in FIG. 4A, a first patterned metallic layer comprising a plurality of first barrier electrodes 402ᵢ₊₁, 402ₗ₊₂, 402ₗ₊₃, 402ₗ₊₄, 402ₗ₊₅, 402ₗ₊₆ may be formed over the insulating layer in a first direction, in particular a first diagonal direction. As shown in FIG. 4A, the first barrier electrodes have a staircase shape comprising horizontal and vertical parts arranged at the peripheral area of quantum dot regions 408.

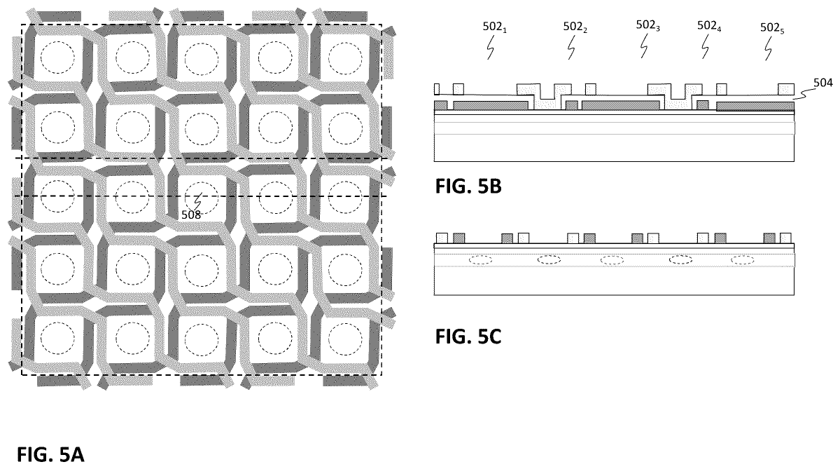

FIG. 5A-5C depict a top view and two cross sections of the semiconductor structure after second fabrication steps in which a second insulating layer 504 is formed over the first barrier electrodes. Further, a second patterned metallic layer comprising a plurality of second barrier electrodes 502ᵢ₊₁, 502ₗ₊₂, 502ₗ₊₃, 502ₗ₊₄, 502ₗ₊₅, 502ₗ₊₆ is formed over the second insulating layer in a second direction, in particular a second diagonal direction. As shown in FIG. 5A, also the second barrier electrodes may have a staircase shape comprising horizontal and vertical parts arranged at the peripheral areas of quantum dot regions 508. The resulting electrode structure form a barrier electrode structure including staircase type electrodes arranged in two opposite diagonal directions, defining quantum dot regions in which quantum wells may be formed, separated by barrier regions. The double barrier gate structure provided over the barrier regions are used to locally control the coupling between neighboring quantum dots. This way, a barrier electrode structure is formed that is similar to the barrier structure described with reference to FIG. 3A allowing locally addressable coupling barriers in a two-dimensional quantum dot array.

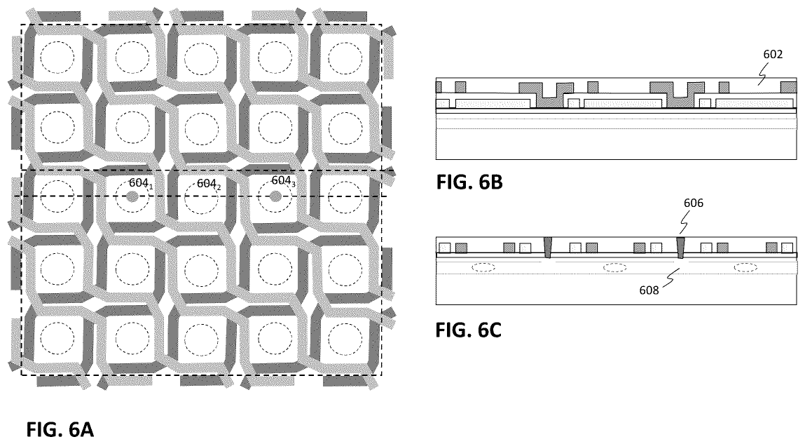

FIG. 6A-6C depict a top view and two cross sections of the semiconductor structure after third fabrication steps wherein a further third insulating layer 602 may be formed over the barrier electrode structure. Further, in this step a readout region within the quantum dot regions may be selected in which a SET transistor may be formed. The readout region may include a number of quantum dot regions 604₁, 604₂, 604₃, in this example three quantum dot regions which may be used in the formation of source and drain regions of the

SET transistor and the island of the SET transistor. Lithography and etching steps may be used to form nano-scale openings through the first, second and third insulating layer to expose at least one semiconductor layer of the one or more semiconductor layers in which the quantum dots are formed. Nano-scale metallic vias 606 are subsequently formed in the openings to provide a galvanic connection between areas in the semiconductor layer which may form the source and drain of a SET transistor and metallic electrode structures that are formed in further fabrication steps. The nano-scale metallic via may form a metal semiconductor contact. In some embodiments, a diffusion step may be used to form a diffusion area 608 at the metal semiconductor contact to improve Ohmic behavior of the galvanic connection.

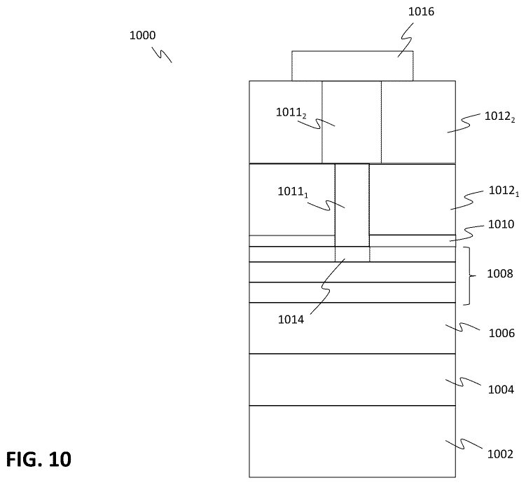

In an embodiment, a nanoscale metal contact structure may be used that is described with reference to FIG. 10. As shown in this figure, a silicon germanium SiGe quantum well structure 1008 may be provided on a silicon substrate 1002. A germanium layer and a graded silicon germanium layer may be provided between the silicon substrate and the quantum well structure. The silicon germanium quantum well may include a SiGe/Ge/SiGe strained quantum well structure. An example of such structure is described in the article by Sammak et. al., Shallow and Undoped Germanium Quantum Wells: A Playground for Spin and Hybrid Quantum Technology, Advanced Functional Materials, 23 Jan. 2019, which hereby may be incorporated by reference into this application. Further, a thin silicon capping layer and an insulating layer 1012₁ may be provided over the quantum well structure. Vertical Ohmic contacts to the germanium quantum well layer may be realized by forming a hole in the insulating layer and the capping layer using e.g. anisotropic reactive ion etching to expose the SiGe layer and forming a metal via 1011₁ in the opening that contacts the SiG or Ge layer. An annealing step may provide some diffusion of the metal into the SiGe to form a direct metal contact with the Ge quantum well layer. Unlike silicon based platforms such as SiMOX or Si/SiGe hetetrosructures, Ge/SiGe do not require high fluence P ion implantation followed by Ti:Pt metallic contacts in order to form n++ doped low resistance metallic contact. Instead a low resistance contact can be made by contacting the Ge quantum well layer directly. This way, nano-scale vias can be realized to directly contact the Ge layer. Further metallic via structures 1011₂ in additional insulating layers 1012₂ may be formed terminating the metal structure with an electrode 1016 that is provided on the surface of insulator 1012₂. The cross-sectional dimensions of the nano-scale metallic vias (i.e. width and/or diameter) may be selected between 400 and 20 nm, preferably between 200 and 40 nm.

In an embodiment, metals for the metal vias include Al, Nb, NbN, TIN, NbTiN. These metals will become superconducting below a certain critical temperature. Thus providing very low loss electrodes. In a further embodiment, platinum may be used as a metal for the vertical vias thereby forming Pt—SiGe or Pt—Ge contact. An annealing step may be used to form an alloy at the interface of this contacts in to form a platinum silicide compound such as platinum silicide PtSi or platinum germanosilicide PtSiGe or a platinum germanide compound such as platinum germanide PtGe; These platinum silicide and germanide alloys will become superconducting below a critical temperature thus providing very low loss superconducting ohmic contacts with the quantum well.

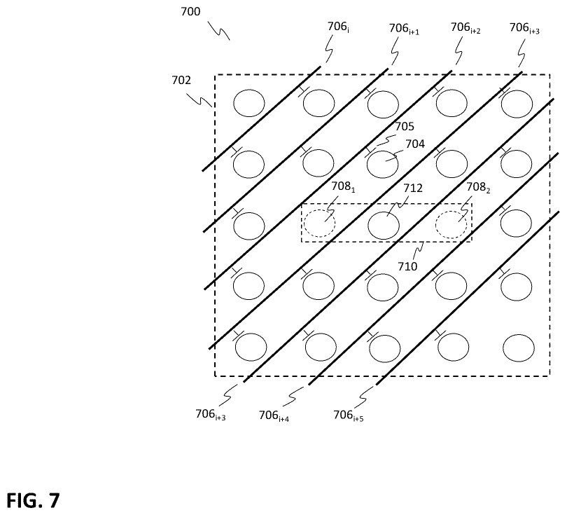

The integrated semiconductor structure of FIG. 6 will subsequently be processed to form both an integrated SET transistor and a gate electrode structure as schematically illustrated in FIG. 7. This figure depicts a schematic of an integrated quantum dot structure including an array of quantum dot regions wherein quantum dot regions in a readout region 710 are configured as a SET transistor. The SET transistor may include a source region 708₁ and drain region 708₂ and an island 712 connected via tunnel barriers to the island. Further, quantum dot regions located around the SET transistor may include a gate structure, e.g. a plurality of electrodes arranged in a predetermined direction over the structure for inducing quantum wells in the quantum dot regions. A gate electrode may include a plurality of plunger gates, wherein a plunger gate 705 may be used to form a quantum well in the quantum dot region.

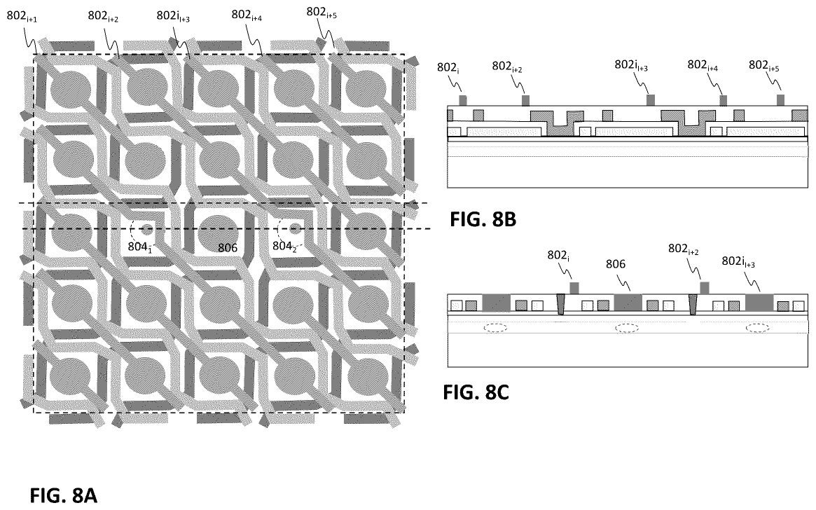

FIG. 8A-8C depict a top view and two cross sections of the semiconductor structure after fourth fabrication steps, which include the formation of a (plunger) gate electrode structures 802ₗ, 802ₗ₊₁, 802ₗ₊₂, 802₁₊₃, 802ₗ₊₄, 802ₗ₊₅, on top of the semiconductor structure as shown in FIG. 6A-6C. Hence, each gate electrode defines a row (in this case a diagonal row) of plunger gates for the quantum dot areas, except for the quantum dot areas 804₁, 804₂, 806 that are located within the readout area for the SET transistor. As shown in FIG. 8A, when forming the electrode structure, a separate plunger gate 806 for the SET transistor may be formed. Further, no plunger gates are formed at the dot regions 804₁, 804₂ for allowing contact to the vias in a further process step. The formation of this structure may be realized based on lithography steps to form openings for the plunger gates and deposition steps for depositing metallic gate electrodes. These gate electrode structures may include plunger gates arranged in the center of the quantum dot regions so that when a voltage is applied to these gates a quantum well is formed in the one or more semiconductor layers.

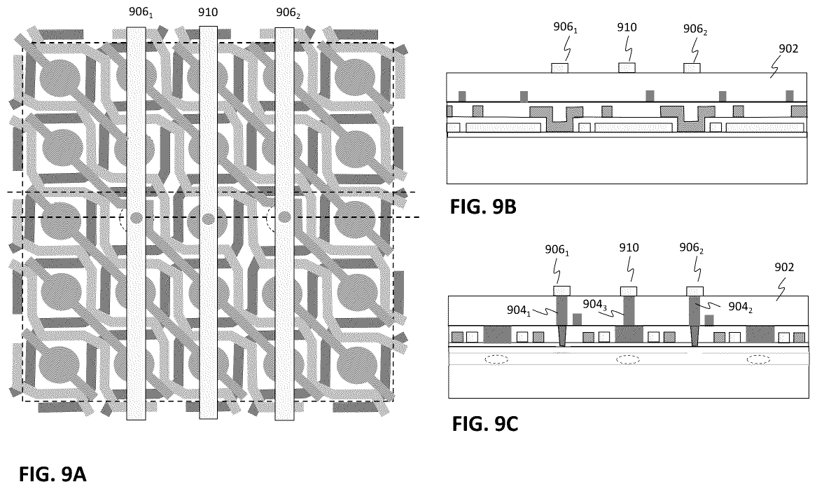

FIG. 9A-9C depict a top view and two cross sections of the semiconductor structure after fifth fabrication steps, which includes the formation of a fourth insulating layer 902 over the semiconductor structure of FIG. 8A-8C and the formation of metallic vias 904₁, 904₂, 904₃ in the fourth insulating layer to provide a galvanic connection between the semiconductor layer and source and drain electrodes 906₁, 906₂ and a connection between the plunger gate of the SET transistor and the SET gate electrode 910, which are provided on the fourth insulating layer. Thereafter, further insulating layers and/or passivation layers may be provided over the semiconductor structure.

Hence, the formation of quantum dots structures comprising an integrated SET readout as described above allows dense integration of large area quantum dot structures. Further, the quantum dot structures include addressable barrier regions allowing quantum dots to be configured as qubits and allowing qubits to interact with each other.

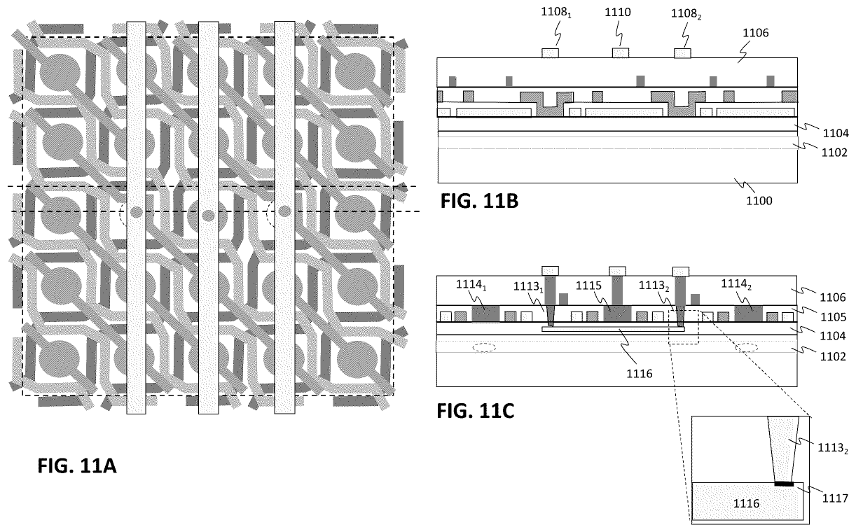

FIG. 11A-11C depict a top view and two cross sections of the semiconductor structure according to a further embodiment of the invention. This semiconductor structure is similar to the semiconductor structure described with reference to FIG. 9A-9C however in this embodiment the SET transistor is formed over the semiconductor layers.

As shown in the figures, the semiconductor structure includes a substrate 1100, one or more semiconductor layers 1102 provided over the semiconductor layers, a layer 1104 comprising a metallic island 116 of the SET transistor, a layer including the barrier electrodes, the gate electrodes 1114_{1,2} for forming quantum wells in the semiconductor layers, metallic vias 1113_{1,2} connecting the metallic island with electrodes and a plunger gate 1115 for controlling the SET transistor and a layer for isolating the source, drain and gate electrodes of the SET electrodes from the rest of the electrode structures using vertical metallic vias. The tunnel junctions of the SET transistor may be formed during the formation of the metallic vias 1113_{1,2}. For example, after realizing openings in the insulating layer 1105 to expose parts of the metallic island, a controlled oxidation process may be used to form an oxide layer 1117 that functions as a tunnel barrier. Thereafter, metallic vias may be realized so that a tunnel barrier is realized between the metallic island 1116 and the metallic via 1113_{1,2} as shown in the inset. Thus, also in this embodiment, a highly integrated SET readout structure is realized wherein the quantum dot regions are provided around the SET transistor.

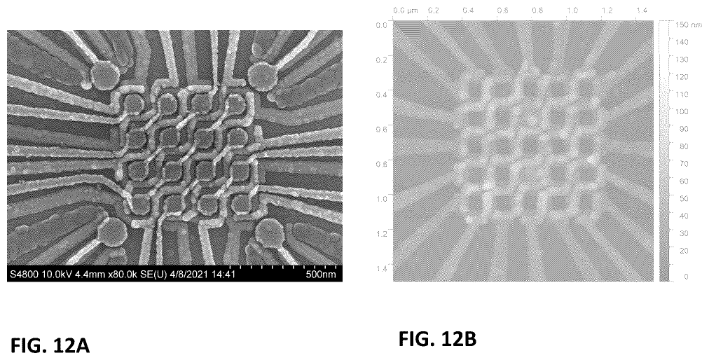

FIG. 12A and 12B depicts pictures of 2D quantum dot arrays that are realized based (part of) the fabrication steps as described with reference to FIG. 4-9. FIG. 12A shows an example of a 4×4 quantum dot array comprising an addressable double barrier gate structure, but does not include array does not include a SET structure. FIG. 12B depicts a picture of a 5×5 quantum dot array including comprising an addressable double barrier gate structure and integrated SET structure as described with reference to the embodiments in this application.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. Integrated quantum dot structure comprising:
one or more semiconductor layers arranged on a substrate;
a single electron tunneling (SET) transistor formed in or over the one or more semiconductor layers, the SET transistor comprising a source and a drain connected by tunneling junctions to a conductive island;
a plurality of quantum dot regions arranged around the SET transistor, the plurality of quantum dot regions being formed in the one or more semiconductor layers and the SET transistor being capacitively coupled to the plurality of quantum dot regions and being configured to readout the plurality of quantum dot regions;
one or more insulating layers provided over the SET transistor and the quantum dot regions;
a source electrode and a drain electrode arranged over the one or more insulating layers; and,
first and second nano-scale metallic vias connecting the source and drain of the SET transistor to the source and drain electrodes over the one or more insulating layers respectively.

2. The integrated quantum dot structure according to claim 1 further comprising:
a third nano-scale metallic via connecting a plunger electrode that is capacitively connected to the conductive island to a gate electrode arranged over the one or more insulating layers.

3. The integrated quantum dot structure according to claim 1 wherein the SET transistor is formed in the one or more semiconductor layers.

4. The integrated quantum dot structure according to claim 3 wherein the conductive island is a quantum dot region formed in the one or more semiconductor layers and wherein the source and drain region regions of the SET are formed in the one or more semiconductor layers.

5. The integrated quantum dot structure according to claim 3 wherein one end of the first nano-scale metallic via and one end of the second nano-scale metallic via form ohmic contacts with the one or more semiconductor layers.

6. The integrated quantum dot structure according to claim 1 wherein the SET transistor is formed in a metallic or doped layer formed over the one or more semiconductor layers.

7. The integrated quantum dot structure according to claim 6 wherein a first metallic via connects the source electrode with the source of the SET transistor and wherein a second metallic via connects the drain electrode with the drain of the SET transistor.

8. The integrated quantum dot structure according to claim 1 wherein quantum dot regions in the plurality of quantum dot regions are separated by barrier regions.

9. The integrated quantum dot structure according to claim 8 further comprising:
a barrier electrode structure comprising:
a first barrier electrode arranged in one direction over the quantum dot structure;
a second barrier electrode arranged in a second direction over the quantum dot structure; and
the first barrier electrode and second barrier electrode crossing each other at a first barrier region selected from the barrier regions, the first and second barrier electrode forming a barrier electrode pair for controlling the-a coupling between a first quantum dot and a second quantum dot separated by the first barrier region.

10. The integrated quantum dot structure according to claim 1 wherein the dimensions of the quantum dot regions are selected between 200 and 20 nm.

11. The integrated quantum dot structure according to claim 1 wherein the plurality of quantum dot regions forms a 2D array of quantum dot regions or a 3D array of quantum dot regions.

12. The integrated quantum dot structure according to claim 1 wherein cross-sectional dimensions of the first and second nano-scale metallic vias are selected between 500 and 10 nm.

13. (canceled)

14. A single electron tunneling (SET) quantum dot readout structure comprising:
one or more semiconductor layers arranged on a substrate;
a quantum dot connected by tunnel junctions to a source area and a drain area, the quantum dot, the tunnel junctions and the source area and drain area forming a SET transistor being formed in or over the one or more semiconductor layers;
the SET transistor being configured to read out a plurality of quantum dot structures arranged around the SET transistor and formed in the one or more semiconductor layers, the SET transistor being capacitively coupled to the a plurality of quantum dot regions;
one or more insulating layers provided over the SET transistor;
a source electrode and a drain electrode arranged over the one or more insulating layers; and,
first and second nano-scaled metallic vias connecting the source area and drain area of the SET transistor to the source electrode and drain electrode over the one or more insulating layers respectively.

15. The quantum dot readout structure according to claim 14 further comprising:
a third nano-scale metallic via connecting a plunger electrode that is capacitively connected to the conductive island to a gate electrode arranged over the one or more insulating layers.

16. The quantum dot readout structure according to claim 14 wherein the SET transistor is formed in the one or more semiconductor layers or wherein the SET transistor is formed in a metallic or doped layer formed over the one or more semiconductor layers.

17. The quantum dot readout structure according to claim 14 wherein the cross-sectional dimensions of the first and second nano-scale metallic vias are selected between 400 and 20 nm.

18. The integrated quantum dot structure according to claim 5, wherein the ohmic contacts comprise nano-scale ohmic contacts.

19. The integrated quantum dot structure according to claim 9, wherein the barrier electrodes and/or the first and second nano-scale metallic vias are made of metal that becomes superconductive below a critical temperature.

20. The integrated quantum dot structure according to claim 1, wherein the one or more semiconductor layers include a semiconductor heterostructure, a MOS structure, a semiconductor-on-insulator structure, or geometries comprising finFET. nanowires, hut wire, or self-assembled structures.
